(19) United States
(12) Patent Application Publication
(10) Pub. No.: US 2024/0179857 A1
(43) Pub. Date: May 30, 2024

(54) SMART SEALING USING SENSORS AND CONDUCTIVE INKS

(71) Applicant: Elm Company, Riyadh (SA)

(72) Inventors: Khalid Saud Almuraee, Riyadh (SA); Syed Salman Alam, Riyadh (SA); Muhammad Saleh Saeed Alqurishi, Riyadh (SA); Enrique Gomicia Murcia, Riyadh (SA)

(21) Appl. No.: 18/214,483

(22) Filed: Jun. 26, 2023

Related U.S. Application Data
(60) Provisional application No. 63/429,118, filed on Nov. 30, 2022.

(51) Int. Cl. H05K 5/02

(52) U.S. Cl. CPC H05K 5/0208

(57) ABSTRACT

A system for resisting tampering, comprising: a device comprising a printed circuit board within a housing; at least one tamper sensor; and a conductive ink electrically connected to the printed circuit board and forming a conductive path when applied to a material. The conductive path has a defined electrical property, such as resistance or conductance. The printed circuit board is configured to both measure any changes in the defined electrical property and trigger an alert to a gateway located outside of the system, such as by a Bluetooth Low energy interface. Methods of resisting tampering of a variety of articles using the disclosed system are also disclosed. Articles comprising the disclosed system are also disclosed.

This application claims the benefit of priority to U.S. Provisional Application No. 63/429,118, filed Nov. 30, 2020, which is incorporated by reference in its entirety.

The present disclosure generally relates to a system to resist tampering, wherein the system comprises conductive ink, which in certain embodiments can be applied to a breakable sheet. Embodiments of the present disclosure also relate to methods to detect tampering by using the disclosed system to identify and send notifications of such tampering to a downstream gateway, such as a server.

There is a wide spectrum of solutions for smart sealing currently available, with most of them based on magnetism, close contact, or some other mechanism. For a practical standpoint, however, the existing solutions suffer from limitations that prevent them from fully meeting expectations.

For example, solutions based on paper comprising bacterial cellulose can be difficult and expensive to produce. In this case, raw materials must be obtained from a culture of suitable bacteria and processed to form a paper substrate, raising the costs to unsustainable levels.

In addition, solutions based on flexible cellulose nano-fiber substrates may be too stretchable to provide adequate protection, as the seal can be forcefully opened without raising any alarm. Additionally, this technology is expensive, and the production procedures are complex.

Another common solution uses crystalline inorganic semiconductor materials, supported by the flexible substrate, including semiconductor junctions, light emitting diodes, thin film transistors, etc. The resulting seals are too easy to break, and they often cause false alarms. This approach is also characterized by high manufacturing expenses.

In addition, solutions with paper substrate-based photovoltaic cells also rely on complex technology with production limitations in terms of cost and processes.

Solutions based on magnetic strips present a viable alternative, as they effectively raise alarms when they are breached. On the negative side, however, magnetic fields can be easy to manipulate, and this solution is not flexible as the others.

While solutions based on a Bluetooth connection are effective with alarm notifications at short range, performance cannot be matched when the distance is increased.

Some solutions are tailored for specific use cases, i.e., they are fitted for containers or luggage but are not valid as general-purpose sealing solutions. There are solutions based on multi-sensor monitoring capable of tracking movement, location, temperature, and other environment variables. However, such solutions are vulnerable to tampering. A vast majority of the existing solutions were developed with a method which can be reversed, allowing the seals to be tampered with. Even more problematically, some solutions lack the capacity to use tamper evident seals and detect tampering attempts remotely. Other solutions struggle to balance communication between Bluetooth Low Energy (BLE) and Long-Term Evolution (LTE) as beacon types.

The present disclosure, directed to smart sealing devices comprising conductive ink, can overcome one or more of the problems set forth above and/or other problems of the prior art.

### SUMMARY

In one embodiment, there is disclosed a system for resisting tampering comprising: a device comprising a printed circuit board; at least one tamper sensor; and a conductive ink electrically connected to the printed circuit board, wherein a conductive path is formed when applied to a material, and wherein the conductive path has a defined electrical property, such as at least one of resistance and conductance.

Additional embodiments are directed to methods for resisting tampering of an article comprising: applying to the article a device comprising: a printed circuit board; at least one tamper sensor; and a conductive ink electrically connected to the printed circuit board, wherein a conductive path is formed to the article, the conductive path having at least one electrical property with a defined value. In this embodiment, the method comprises measuring the at least one electrical property to get a measured value and comparing the difference between the measured value and the defined value.

In a further embodiment there is described an article comprising a system for resisting tampering attached thereto, the system comprising: a device comprising a printed circuit board; at least one tamper sensor; and a conductive ink electrically connected to the printed circuit board, wherein a conductive path to the article is formed, said conductive path having at least one electrical property with a defined value.

In certain embodiments, the material on which the conductive ink is applied can be an adhesive sheet, such as a disposable adhesive sheet, including a breakable sticker.

Non-limiting examples of the article according to the present disclosure that may be protected by the disclosed system includes a document, sheet, package, box, shipping container, storage container, electrical appliance, door or window.

### BRIEF DESCRIPTION OF THE DRAWINGS

The accompanying drawings, which comprise a part of this specification, illustrate several embodiments and, together with the description, serve to explain the principles disclosed herein.

FIG. 1 is a block diagram of the main architecture according to one embodiment of the disclosure.

FIG. 2 is a block diagram of a device according to one embodiment of the disclosure.

FIG. 3A is a photograph of the top side of a covered device according to one embodiment of the disclosure. FIG. 3B is a photograph of the bottom side of a covered device of FIG. 3A with spring loaded connectors and limit switch protruding therethrough.

FIG. 4A is an inside view of the device of FIGS. 3A and 3B, with the cover removed. FIG. 4B is the back side of the device of FIG. 4A.

FIGS. 5A and 5B show a microcontroller according to the present disclosure as it reads the voltages and looks for the change in resistance of the conductive adhesive sheet, rather than directly checking the conductivity.

FIG. 6A shows a device according to an embodiment of the disclosure, with FIG. 4A connected to a paper with a conductive silver ink. FIG. 6B shows the concept of FIG. 6A, with a covered device, such as shown in FIG. 3A.

FIG. 7A shows a mobile app capturing data without connection. FIG. 7B shows a mobile app configuration view.

FIG. 8 is a picture showing the communication and packet transmission from seal beacon to cloud.

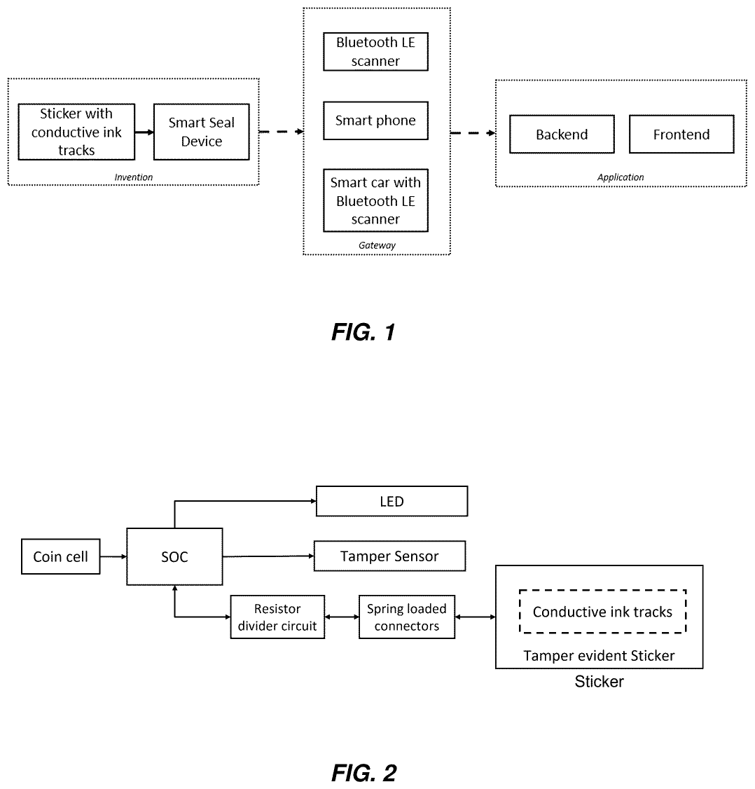

### DETAILED DESCRIPTION

The following detailed description refers to the accompanying drawings. Wherever possible, the same reference numbers are used in the drawings and the following description to refer to the same or similar parts. While several illustrative embodiments are described herein, modifications, adaptations and other implementations are possible. For example, substitutions, additions, or modifications may be made to the components and steps illustrated in the drawings, and the illustrative methods described herein may be modified by substituting, reordering, removing, or adding steps to the disclosed methods. Accordingly, the following detailed description is not limited to the disclosed embodiments and examples. Instead, the proper scope of the invention is defined by the appended claims.

There are numerous cases where detecting the tampering of a sealed object is important. Traditional ways of sealing include using wax seal stamps or, in the case of bigger objects such as boxes, installing active tracking devices with seal detection. There is a lack of solution that can be flexible enough to be used with smaller objects such as envelopes, tender documents, and bigger objects such as sealing a door, boxes or a suitcase.

As evident, most of the existing solutions are reliant on simple tracking devices based on expensive technology and/or technology that consumes a large amount of battery power. In contrast, the present disclosure is directed to a device that can work as a standalone tamper detection system and when combined with a gateway, can work as a real time tamper detection and reporting system.

To address the foregoing needs, there is provided a more practical, cost-effective, and proactive solution for detecting tampering events and securing seals in various industries. Traditional sealing methods have limitations, such as the inability to detect and prevent tampering events in real-time and the requirement for visual inspection. This can lead to security breaches, safety concerns, and compliance issues.

The development of the smart sealing device with conductive ink provides a novel and innovative solution for detecting tampering events in real-time, leading to improved safety, security, and compliance. The use of off-the-shelf Bluetooth gateways or smartphones as the gateway also makes the device more accessible and cost-effective.

The disclosed embodiments have the potential to revolutionize the way seals are secured and monitored in various industries, including supply chain management, document and asset protection, security and surveillance, compliance and regulation, evidence management, authentication and verification, and government. In one embodiment, the use of conductive ink and breakable sticker sheet creates a circuit that is broken if the seal is tampered with, triggering an alert that is sent to the backend system. This real-time notification enables the end user to take immediate action to prevent any further breaches and maintain the integrity of the seal.

Therefore, embodiments of the present disclosure have significant potential to solve real-world problems, improve security, and reduce risks in various industries.

In one embodiment, there is disclosed a system for resisting tampering comprising: a device comprising a printed circuit board; at least one tamper sensor; and a conductive ink electrically connected to the printed circuit board, wherein a conductive path is formed when applied to a material, and wherein the conductive path has a defined electrical property, such as at least one of resistance and conductance.

Additional embodiments are directed to methods for resisting tampering of an article comprising: applying to the article a device comprising: a printed circuit board; at least one tamper sensor; and a conductive ink electrically connected to the printed circuit board, wherein a conductive path is formed to the article, the conductive path having at least one electrical property with a defined value. In this embodiment, the method comprises measuring the at least one electrical property to get a measured value and comparing the difference between the measured value and the defined value.

In a further embodiment there is described an article comprising a system for resisting tampering attached thereto, the system comprising: a device comprising a printed circuit board; at least one tamper sensor; and a conductive ink electrically connected to the printed circuit board, wherein a conductive path to the article is formed, said conductive path having at least one electrical property with a defined value.

In embodiments, the printed circuit board comprises a microcontroller that may be configured to measure any changes in the defined electrical property. The microcontroller may also be configured to wirelessly send an alert if it detects changes in the defined electrical property. Non-limiting examples of the defined electrical property include at least one of resistance and conductance. In certain embodiments, the alert can be sent through a Bluetooth Low energy interface or a Long-Term Energy interface. Similarly, the gateway that is located outside of the system may be configured to receive near field wireless, Bluetooth or other known wireless communication protocols, such as a smart phone.

In embodiments, the printed circuit board is contained within a housing. In addition, the at least one tamper sensor comprises at least one spring-loaded pin that remains depressed when in the housing.

In certain embodiments, the material on which the conductive ink is applied can be an adhesive sheet, such as a disposable adhesive sheet, including a breakable sticker. Sealing applications that rely on flexible electronics, based on conductive ink, are taking advantage of the liquid's conductive properties to detect any damage to the seal. Sealing solutions can be applied in a wide range of industries and different contexts including mechanical seals, boxes, packaging, extrusions, luggage, gates, envelopes, confidential documents and doors. Therefore, one aspect of the present disclosure is directed to a smart sealing device comprising conductive ink applied on a disposable adhesive sheet, such as a breakable sticker, to detect tamper and send notifications.

In one embodiment, the sheet is configured to be conductive on the edges, such as from the use of conductive inks, including those disclosed below. In this embodiment, if the circuit is broken, the device will trigger an alert by changing the packet in the advertisement packet and the nearby gateway will receive the packet and send it to the server. The advertisement packet, within the present context, relates to the advertisement packet of the Bluetooth® Low Energy protocol, as specified by the Bluetooth Special Interest Group (SIG) standards organization. The packet notification will inform the system that the seal has been compromised. This setup provides the end user with the opportunity to immediately report attempted breaches of the seal, such as to a security company or another relevant authority. In one embodiment in which there is no gateway nearby the device will permanently change the information in the packet. This information will be captured later by the gateway.

In one embodiment, the gateway could be a smart phone or a Bluetooth gateway. Once the tamper information has been received on the backend, it can be utilized in different applications and use cases and a custom-based user interface can be designed accordingly.

Conductive inks are one component of the disclosed apparatus. Several conductive materials are appropriate for this purpose, and non-limiting examples include conductive polymers, carbon, organic/metallic compounds, metal precursors, and metal particles and nanoparticulates. In certain embodiments, inks with the best conductive properties comprise metal particles and/or nanoparticulates, such as carbon, silver, copper, graphite, gold, mercury, bronze, nickel, aluminum, and brass. A reason for the improved conductive properties is that the resistivity of the metal particles and/or nanoparticulates is close to that of the bulk material (approximately 2-3 times higher) as opposed to conductive polymers that have significantly higher level of resistivity. The conductive materials disclosed herein can be applied on the back of a paper or combined with an adhesive which will be attached to whatever device needs to be sealed and protected.

In certain embodiments, there is a disposable adhesive sheet, such as a disposable seal sticker. Thus, there is described a non-reversible method for sealing, essentially guaranteeing that no one can tamper with the sealed article. Other non-limiting benefits associated with the disclosed sealing device include:
Use of electronic ink makes mass production cheaper and simplifies the manufacturing process.
The apparatus can use both Bluetooth Low Energy (BLE) and LTE technology for communication.
Smart Seal device controls battery consumption and can maximize the effectiveness of alarms and tracking activities.
Use of ink composition that can be filled with several kinds of conductive materials, such as carbon, silver, copper, graphite, gold, mercury, bronze, nickel, aluminum and brass.
The ability to check multiple parameters for evidence of tampering, such as a change in resistance instead of conductivity.
Using conductive ink to make tracks, are long enough that they possess resistance.

A more detailed description of the various elements that can be used in the present disclosure is provided below. The disclosure is described with respect to the following five components: (1) Tamper evident sticker: (2) Conductive ink; (3) Spring loaded connectors; (4) Bluetooth low energy based system on chip (SOC); and (5) Tamper switch. Each component is explained below in detail separately and then in the last section it is explained as a combined description of the invention.

Tamper Evident Sticker: The tamper evident sticker can be of any size as is configured based on the size of the item on which is it placed. These stickers have cuts on the sides and if someone tries to remove the sticker they tear apart. In one embodiment, the sticker is configured to be breakable, so it is possible to use normal sticker or seal evident sticker, irreversible to have physical evidence of breaking the paper. In general, the sticker can be any sticker material that can carry the conductive ink on it.

Conductive Material: This can be any material that can effectively serve as a conduit for the electrical charge. In one embodiment, a conductive ink is used that can be dispersed on paper and direct the electric current along the path drawn across the paper. The conductive material can be homogenous or composite of several material types, provided they are in a liquid form. One of the main advantages associated with the conductive materials described herein is that it can use various materials and is thus not limited to silver ink.

Ink Material: This can be any ink-based material that can effectively serve as a conduit for the electrical charge. Conductive ink is an ink that can be used to print an object, text or line which conducts electricity, and desirable properties of the ink include oxidation stability, high conductivity, and when applied to a flexible substrate, mechanical flexibility and durability. In some embodiments, these inks use conductive metal particles that possess electricity conductive properties. In various embodiments, the conductive material can be homogenous or composite of several material types, provided they are in a liquid form. Depending on the length of the trace on their conductivity decreases due to resistance. Resistance depends on the length of a line drawn on the paper using this ink. Non-limiting examples of the conductive materials that can be used herein include silver, carbon, graphite, copper, gold, mercury, bronze, nickel, aluminum, brass and combinations thereof.

In certain embodiments, the conductive ink comprises silver. According to these embodiments, the conductive inks can comprise silver particles and/or silver nanoparticles. Non limiting examples of such conductive inks comprising silver include water-based conductive coatings, pigmented with highly conductive silver-coated copper flake. In other embodiments, the conductive ink comprises graphite or graphene, which can be particles and/or nanoparticles. In further embodiments, the conductive ink comprises graphene, which is a single carbon layer of graphite. In these embodiments, the use of graphene can increase strength and reduce corrosion.

Spring Loaded Connectors: Spring-loaded connectors create an electrical contact between two components. They are also known as Spring loaded contacts, Spring probes and pogo pins. In one embodiment, these connectors are made up of 3 machined components and assembled with an internal spring to provide the range of movement required. These components are typically electroplated with gold over nickel to ensure excellent electrical conductivity, durability and corrosion protection throughout the life of the product. The spring inside the connectors ensures even and low resistance connections.

Bluetooth low energy SOC: In one embodiment, a Nordic Semiconductor SOC (System on Chip) nRF52832 was used in development of the described device; however, any other Bluetooth low energy controller can be used. It is a low power consumption microcontroller. This microcontroller has various peripherals and features. It is built around an Arm cortex-M4 CPU with a floating point unit running at 64 Mhz.

Tamper Switch: This is a tamper switch with normally open connections. When the switch is pressed it becomes closed and current can pass through it. The spring inside this switch is soft that it does not push to normal condition when pressed.

In one embodiment, the device according to the disclosed embodiment comprises at least 3 different parts: the electronics circuit, the sensors, and the conductive sticker as shown in FIG. 2. With reference to FIG. 2, showing a block diagram of the device according to one embodiment, there is at the core of the device a SOC (System on Chip) which consists of ARM controller and a Bluetooth Low energy interface. In one embodiment, a light emitting diode is connected to the controller for indication of connection to a mobile application for activation and deactivation of the device. The controller remains in sleep mode when it is not activated. In the sleep mode, it is still broadcasting Bluetooth advertisement packets at reduced intervals to extend the battery life, such as a packet interval of 10 seconds. Advertisement is important because without it a smart phone could not connect to the device.

To activate the device, it must be connected to a smart phone through its application. Users can configure the device from this application and decide which sensors will be activated or deactivated. In addition to that, the application can be used to control access to the device, location of the smart phone can be fetched to know where the device was installed as the device does not have GPS and set up numerous other parameters to best correspond to practical requirements. Once the device is activated it starts emitting packets at a higher rate, such as at a packet interval of 5 seconds.

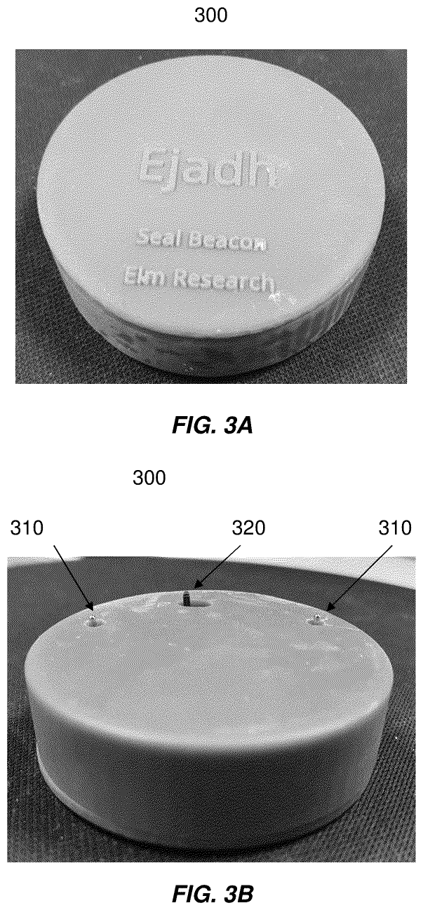

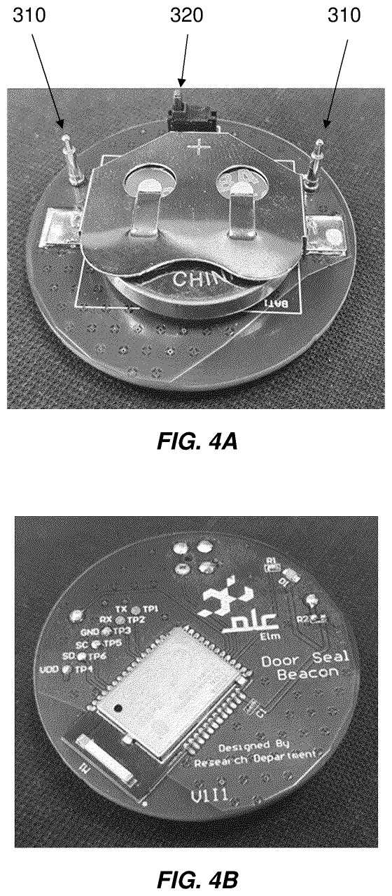

With reference to FIG. 3B, there is shown on the bottom side of the device spring loaded connectors and a limit switch. FIG. 4A shows an inside view of the device. The limit switch is used as a tamper switch which is connected to the SOC general purpose input/output (GPIO) pin. This GPIO pin is checked on an interrupt in the controller. As shown in FIGS. 3A and 4A, the head of the tamper switch is pressed when the device is installed on the sticker by double sided tape. Once the device is installed and activated it then continuously checks for interruption. In case someone tries to take out the device the switch is released, and an interrupt is called in the SOC. This changes the BLE advertisement packet.

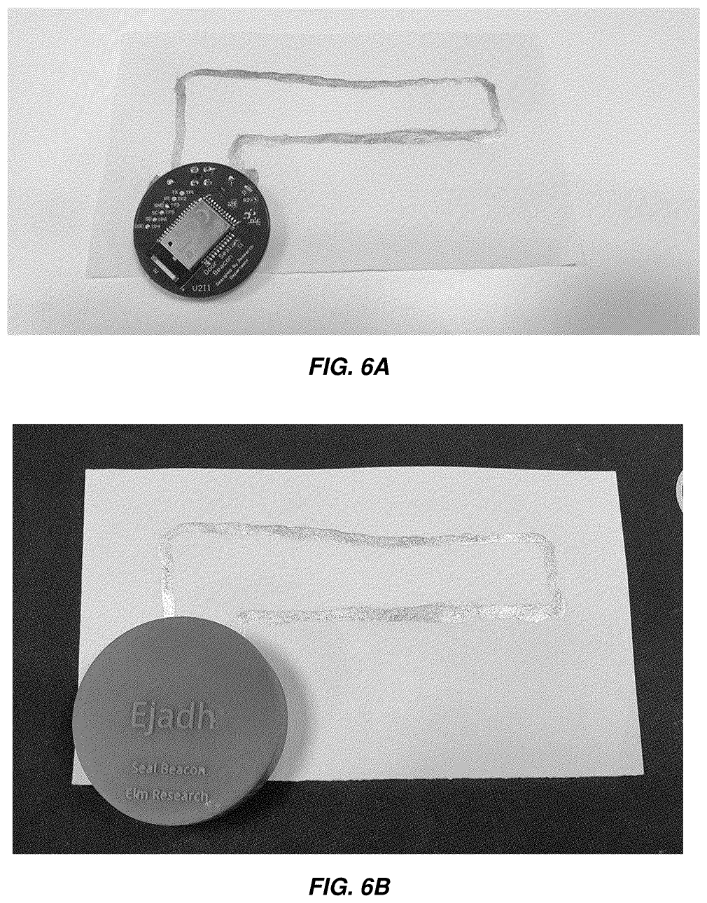

With reference to FIG. 3A, it is shown that there can be multiple sensors (310, 320) attached to the disclosed device. The tamper sensor is one of them, which includes a switch (320) which is pushed down when the device is installed and is released when someone tries to tamper with the device. For example, switch (320) may comprise a limit switch. Another sensor is the conductive sensor, which is a conductive path drawn on the sticker sheet, with two ends of the path connected by the spring-loaded connectors in the device (310). The conductive ink material has some resistance that corresponds to path length, and exact resistance for each particular case can be measured by the microcontroller using the voltage divider method, which analyzes the voltage stored in the device at the time of activating. A non-limiting embodiment is shown in FIGS. 6A and 6B. In this embodiment, if the conductive path defined by the conductive ink is broken, tampering will become apparent. Use of both a conductive sensor in combination with switch (320), such as a limit switch, improves security, since whereas the conductive sensor detects if the seal has been tampered with (i.e. broken), the switch (320) detects if an attempt has been made to remove the seal from the object it is attached to.

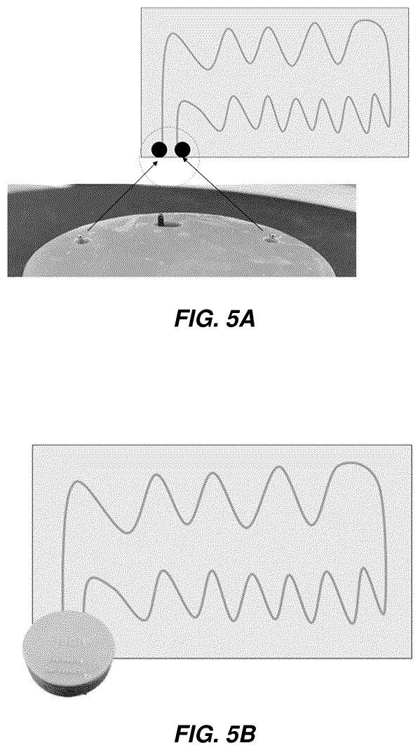

In one embodiment of the disclosed method of use of the device disclosed herein, the first step is to place the sticker sheet on the surface of the object to seal. After that is completed, the device can be installed on the designated location. With reference to FIGS. 5A and 5B, the microcontroller reads the voltages and looks for the change in resistance of the conductive sticker sheet, rather than directly checking the conductivity. This is done to make sure that it is impossible to tamper with the device. The resistance of the adhesive sheet will change if someone tries to bypass the conductive sticker sheet and access the device underneath it.

The controller remains in sleep mode when it is not activated. In the sleep mode, it is still broadcasting Bluetooth advertisement packets at a packet interval of 10 seconds to extend the battery life. Advertisement is important because without it a smartphone could not connect to the device. To activate the device, it must be connected to a smartphone through its application. Users can configure the device from this application and decide which sensors (Tamper or conductive ink) will be activated or deactivated. At the time of activation or deactivation of the device from the smartphone application, the smartphone application also fetches the location of the smartphone. This information can be sent to the server as a record where the device was activated or deactivated. Once the device is activated it starts emitting packets at a higher rate, with the interval of 5 seconds.

Information about attempted tampering with the seal is included in the next packet that is broadcast by the device. The information in the packet can include one or more of the following:
Device hardware version and revision;
Device firmware version and revision;
Types of sensors activated;
Tampering information from each sensor;
Battery voltage of the device; and
MAC address of the device.

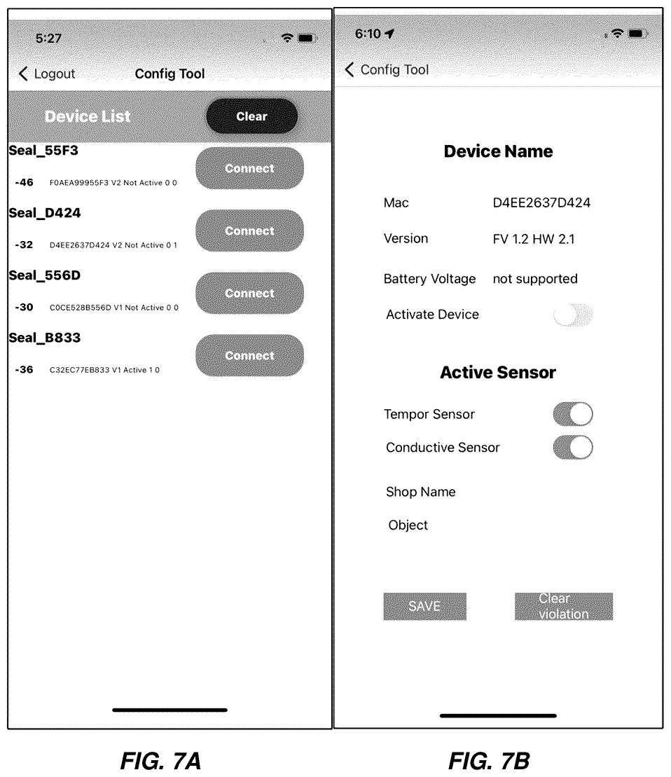

As exemplified in FIGS. 7A and 7B, this information can be displayed by a smart phone without having to connect to the device. The role of a gateway could be played by a smartphone or a fixed Bluetooth receiver connected to the cloud that receives the information packets and sends them to the backend, where the end application is deployed. In case there is an attempt to tamper with the device, changed status will continue to be included in the transmitted packets until the device is reset by the administrator from the smartphone application.

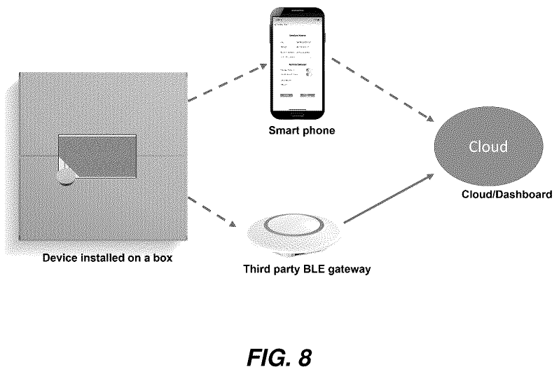

In some embodiments, a third-party gateway may be used. It is important to note that while a middleware can be used but is not essential for the system to work. This gateway will act as a means of transmitting the data from the disclosed device to the cloud. The gateway could be a smart phone or any Bluetooth low energy packet receiving gateway. FIG. 8 exemplifies one embodiment which shows the communication and packet transmission from seal beacon to cloud.

Non-limiting potential commercial uses for the various embodiments disclosed herein can be found in the following, which may be in the form of a smart sealing device with a conductive ink and breakable sticker sheets.

Smart Sealing: This mechanism can be used to detect tampering on sealed stores, doors and countless other individual appliances and items after they are sealed because of a violation

Supply Chain Management: In one embodiment, the device disclosed herein can be used to secure and monitor the integrity of packages, products, and containers during transportation and storage. The device can be attached to boxes, pallets, or containers, providing real-time notifications of any tampering events, as well as locations of products during transportation and storage.

Document and Asset Protection: In one embodiment, the device disclosed herein can be used to secure important documents such as contracts, tenders, and confidential files. The device can be attached to envelopes, folders, and cabinets, providing real-time notifications of any unauthorized access or tampering events.

Security and Surveillance: In one embodiment, the device disclosed herein can be used to secure doors, windows, and gates, providing real-time notifications of any unauthorized access or tampering events. The device can also be used to secure safes, lockers, and cabinets, providing real-time notifications of any attempts to break in or tamper with the lock.

Compliance and Regulation: In one embodiment, the device disclosed herein can be used in industries where compliance and regulation are critical, such as pharmaceuticals, food and beverage, and transportation. The device can be attached to products, packages, and containers, providing real-time notifications of any tampering events that could compromise the safety and quality of the products.

Evidence Management: In one embodiment, the device disclosed herein can be used in law enforcement and legal scenarios to secure and monitor the integrity of evidence. The device can be attached to evidence bags, providing real-time notifications of any tampering events that could compromise the integrity of the evidence.

Authentication and Verification: In one embodiment, the device disclosed herein can be used for authentication and verification purposes in various scenarios, such as verifying the authenticity of a product or package, or ensuring the integrity of a vote in elections.

Government: In one embodiment, the device disclosed herein can be used to secure voting ballots, official documents, and other sensitive assets in the government sector. The device can provide real-time tamper detection and prevention and can be integrated with different security systems and protocols.

Alternative embodiments of the present disclosure are envisaged in which the device may communicate with the gateway using any known wireless communications standard, including, but not limited to, any one or more of 2G, 3G, 4G, LTE-M or NB-IOT. In other words, the device is not restricted to using Bluetooth®. Such alternative wireless standards may comprise long range standards.

In yet further alternative embodiments, the device may be provided with a communications device local to it, enabling the device to communicate directly with the server, without requiring an external gateway. The communications device may provide any one or more of: 2G, 3G, 4G, LTE-M or NB-IOT communication.

While the present disclosure has been shown and described with reference to particular embodiments thereof, it will be understood that the present disclosure can be practiced, without modification, in other environments. The foregoing description has been presented for purposes of illustration. It is not exhaustive and is not limited to the precise forms or embodiments disclosed. Modifications and adaptations will be apparent to those skilled in the art from consideration of the specification and practice of the disclosed embodiments.

Computer programs based on the written description and disclosed methods are within the skill of an experienced developer. Various programs or program modules can be created using any of the techniques known to one skilled in the art or can be designed in connection with existing software. For example, program sections or program modules can be designed in or by means of .Net Framework, .Net Compact Framework (and related languages, such as Visual Basic, C, etc.), Java, C++, Objective-C, HTML, HTML/AJAX combinations, XML, or HTML with included Java applets.

Moreover, while illustrative embodiments have been described herein, the scope of any and all embodiments having equivalent elements, modifications, omissions, combinations (e.g., of aspects across various embodiments), adaptations and/or alterations as would be appreciated by those skilled in the art based on the present disclosure. The limitations in the claims are to be interpreted broadly based on the language employed in the claims and not limited to examples described in the present specification or during the prosecution of the application. The examples are to be construed as non-exclusive. Furthermore, the steps of the disclosed methods may be modified in any manner, including by reordering steps and/or inserting or deleting steps. It is intended, therefore, that the specification and examples be considered as illustrative only, with a true scope and spirit being indicated by the following claims and their full scope of equivalents.

What is claimed is:

1. A system for resisting tampering, the system comprising:
a device comprising a printed circuit board;
at least one tamper sensor; and
a conductive ink electrically connected to the printed circuit board and capable of forming a conductive path when applied to a material, wherein the conductive path has a defined electrical property.

2. The system of claim 1, wherein the printed circuit board is contained within a housing and comprises a microcontroller configured to measure any changes in the defined electrical property.

3. The system of claim 2, wherein the microcontroller is configured to send an alert if it detects changes in at least one of resistance and conductance.

4. The system of claim 1, wherein the printed circuit board comprises a device to wirelessly communicate data to a gateway located outside of the system.

6. The system of claim 5, wherein the device to wirelessly communicate data comprises a Bluetooth Low energy interface.

7. The system of claim 5, wherein the gateway located outside of the system is a smart phone configured to receive near field wireless, Bluetooth or other known wireless communication protocol.

8. The system of claim 2, wherein the at least one tamper sensor comprises at least one spring-loaded pin that remains depressed when in the housing.

9. The system of claim 1, wherein the material on which the conductive ink is applied is a disposable adhesive sheet.

10. The system of claim 1, wherein the conductive ink silver particles and/or nanoparticles.

11. A method of resisting tampering of an article, comprising applying to the article a device comprising:
a printed circuit board;
at least one tamper sensor; and
a conductive ink electrically connected to the printed circuit board, wherein a conductive path is formed to the article, the conductive path having at least one electrical property with a defined value,
the method comprises measuring the at least one electrical property to get a measured value and comparing the difference between the measured value and the defined value.

12. The method of claim 11 wherein the at least one electrical property is selected from conductance and resistance.

13. The method of claim 12, wherein the article is chosen from a document, a sheet comprising an adhesive side, a package, a box, a shipping container, a storage container, an electrical appliance, a door and a window.

14. The method of claim 11, wherein the printed circuit board comprises a microcontroller that is configured to measure any changes in at least one of resistance and conductance, and configured to send an alert if it detects changes in at least one of resistance and conductance.

15. The method of claim 14, wherein the printed circuit board comprises a device to wirelessly communicate data using near field wireless or a Bluetooth Low energy interface to a gateway that is located outside of the system.

16. An article comprising a system for resisting tampering attached thereto, the system comprising:
a device comprising a printed circuit board;
at least one tamper sensor; and
a conductive ink electrically connected to the printed circuit board wherein a conductive path to the article is formed, said conductive path having at least one electrical property with a defined value.

17. The article of claim 16, which is chosen from a document, a sheet comprising an adhesive side, a package, a box, a shipping container, a storage container, an electrical appliance, a door and a window.

18. The article of claim 16, wherein the printed circuit board comprises a microcontroller that is configured to measure any changes in at least one of resistance and conductance, and configured to send an alert if it detects changes in at least one of resistance and conductance.

19. The article of claim 16, wherein the printed circuit board comprises a device to wirelessly communicate data to a gateway that is located outside of the system.

20. The article of claim 16, wherein the gateway is a smart phone.
